(19) United States
(12) Patent Application Publication
(10) Pub. No.: US 2019/0172962 A1
(43) Pub. Date: Jun. 6, 2019

(54) ENCAPSULATION STRUCTURE AND SOLAR CELL MODULE

(71) Applicant: Industrial Technology Research Institute, Hsinchu (TW)

(72) Inventors: Wei-Sheng Lin, Taoyuan City (TW); Chien-Rong Huang, Hsinchu City (TW); Tung-Po Hsieh, Hsinchu City (TW)

(73) Assignee: Industrial Technology Research Institute, Hsinchu (TW)

(21) Appl. No.: 15/857,625

(22) Filed: Dec. 29, 2017

(30) Foreign Application Priority Data
Dec. 5, 2017 (TW) 106142492

(51) Int. Cl. H01L 31/048; H01L 31/05

(52) U.S. Cl. CPC H01L 31/0481; H01L 31/0504

(57) ABSTRACT

An encapsulation structure and a solar cell module are provided, wherein the encapsulation structure is disposed on the light incident surface of the solar cell module and is consisted of a thermoplastic protective layer, a transparent water-barrier layer, and an adhesive layer. The thermoplastic protective layer is disposed on the outermost layer of the light incident surface, and the material thereof includes thermoplastic polyurethane (TPU), thermoplastic polyolefin (TPO), or thermoplastic elastomer (TPE). The transparent water-barrier layer is disposed between the adhesive layer and the thermoplastic protective layer.

### CROSS-REFERENCE TO RELATED APPLICATION

This application claims the priority benefits of Taiwan application serial no. 106142492, filed on Dec. 5, 2017. The disclosure of which is hereby incorporated by reference herein in its entirety.

### TECHNICAL FIELD

The disclosure relates to an encapsulation structure and a solar cell module.

### BACKGROUND

The encapsulation material for the solar cell module generally adopts glass or ethylene tetrafluoroethylene (ETFE) as the protective layer and the water-barrier layer in present.

However, although glass has the function of water barrier, it is neither lightweight nor flexible and is readily fragmented. Moreover, the water-barrier effect of ETFE used as the protective layer is poor, and the surface hardness thereof is too poor to prevent the surface from being scratched.

Therefore, a simplified encapsulation structure with high light transmittance and low water permeability is in need for lightweight and flexible of the solar cell module.

### SUMMARY

According to an embodiment of the disclosure, an encapsulation structure of a solar cell module is disposed on the light incident surface of the solar cell module. The encapsulation structure is consisted of a thermoplastic protective layer, a transparent water-barrier layer, and an adhesive layer. The thermoplastic protective layer is disposed on the outermost layer of the light incident surface, and the material thereof includes thermoplastic polyurethane (TPU), thermoplastic polyolefin (TPO), or thermoplastic elastomer (TPE). The transparent water-barrier layer is disposed between the adhesive layer and the thermoplastic protective layer.

According to another embodiment of the disclosure, an encapsulation structure of a solar cell module is disposed on the back light surface of the solar cell module. The encapsulation structure is consisted of a thermoplastic protective layer, a water-barrier layer, and an adhesive layer. The thermoplastic protective layer is disposed on the outermost layer of the back light surface, and the material thereof includes TPU, TPO, or TPE. The water-barrier layer is disposed between the adhesive layer and the thermoplastic protective layer.

According to yet another embodiment of the disclosure, a solar cell module includes a front plate encapsulation structure, a backplate encapsulation structure, and a plurality of solar cells encapsulated between the front plate encapsulation structure and the backplate encapsulation structure. The front plate encapsulation structure is consisted of a first thermoplastic protective layer, a first water-barrier layer, and a first adhesive layer, wherein the first water-barrier layer is disposed between the first thermoplastic protective layer and the first adhesive layer. The material of the first thermoplastic protective layer includes TPU, TPO, or TPE. The first water-barrier layer is a transparent water-barrier layer. The solar cells are directly in contact with the first adhesive layer.

Based on the above, in the disclosure, by including a specific protective layer with a single water-barrier layer and a single adhesive layer, the effects of high light transmittance and low water permeability for the front plate encapsulation structure may be achieved, and the effect of low water permeability for the backplate encapsulation structure may also be achieved. Moreover, the solar cell module of the disclosure has the front plate encapsulation structure or the backplate encapsulation structure, and therefore not only has the features of lightweight and flexibility, but the life and reliability of the solar cell module may also be increased at the same time.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1A is a schematic of the encapsulation structure of a solar cell module according to the first embodiment of the disclosure.

FIG. 1B is a schematic of the encapsulation structure of a solar cell module according to the second embodiment of the disclosure.

FIG. 2 is a schematic of a solar cell module according to the third embodiment of the disclosure.

### DETAILED DESCRIPTION OF DISCLOSED EMBODIMENTS

Embodiments are provided hereinafter and described in detail with reference to figures. However, the embodiments provided are not intended to limit the scope of the disclosure. Moreover, the figures are only descriptive and are not drawn to scale, and different layers or regions may be enlarged or shrunk to be shown in a single figure. Moreover, although different elements, regions, and/or film layers are described using, for instance, “first” and “second” in the specification, the elements, regions, and/or film layers should not be limited to these terms. Instead, these terms are only used to distinguish an element, region, or film layer from another element, region, or film layer. Therefore, a first element, region, or film layer discussed below may be referred to as a second element, region, or film layer without violating the teaching of the embodiments. Moreover, to facilitate understanding, the same elements in the following are described with the same reference numerals.

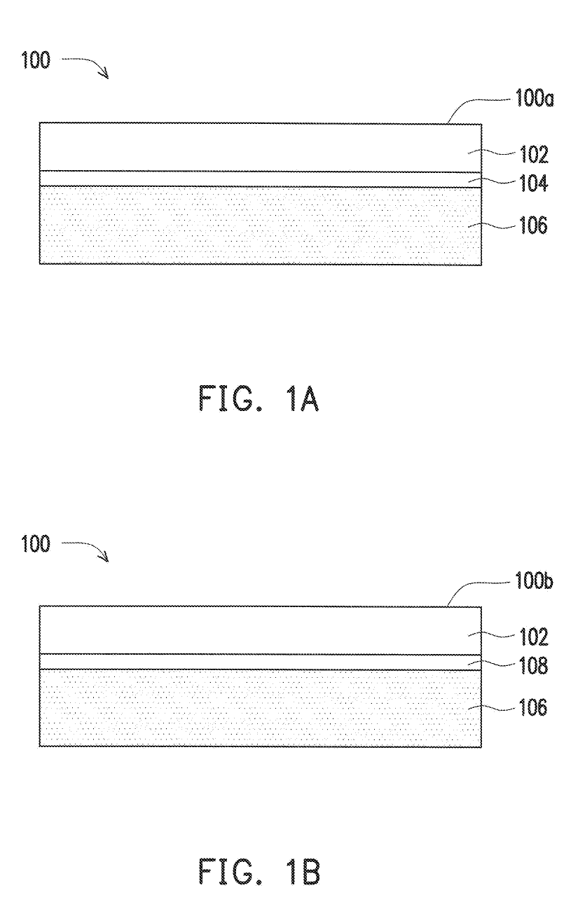

FIG. 1A is a schematic of the encapsulation structure of a solar cell module according to the first embodiment of the disclosure.

Referring to FIG. 1A, an encapsulation structure 100 of the disclosure is used in a solar cell module and is generally disposed on a light incident surface 100a of the solar cell module. The encapsulation structure 100 is consisted of a thermoplastic protective layer 102, a transparent water-barrier layer 104, and an adhesive layer 106. The thermoplastic protective layer 102 is disposed on the outermost layer of the light incident surface 100a. In other words, there are no other structural layers present besides the thermoplastic protective layer 102, and the thermoplastic protective layer 102 is directly exposed to the external environment. The material of the thermoplastic protective layer 102 includes a thermoplastic polyurethane (TPU), a thermoplastic polyolefin (TPO), or a thermoplastic elastomer (TPE). The transparent water-barrier layer 104 is disposed between the adhesive layer 106 and the thermoplastic protective layer 102. In an embodiment, the transparent water-barrier layer 104 may include a light-permeable material such as ultra-thin glass or a polymer having TFE (thin film encapsulation), wherein the ultra-thin glass refers to a glass having a thickness of 400 microns or less, alternatively a thickness of 150 microns or less. If the transparent water-barrier layer 104 is the polymer having TFE, then the polymer having TFE may include, for instance, polycarbonate (PC), polyethylene naphthalate (PEN), polyethylene terephthalate (PET), fluoropolymer, polyvinyl fluoride (PVF), ethylene tetrafluoroethylene (ETFE), or polyvinylidene difluoride (PVDF). The material of the adhesive layer 106 is not particularly limited, and may be a thermoplastic adhesive layer or a thermosetting adhesive layer. In an embodiment, the material of the adhesive layer 106 includes TPU, TPO, TPE, or ethylene vinyl acetate (EVA). If the same material is used for the adhesive layer 106 and the thermoplastic protective layer 102, then the same process conditions may be applied during encapsulation to facilitate process control.

FIG. 1B is a schematic of the encapsulation structure of a solar cell module according to the second embodiment of the disclosure, wherein the same reference numerals as those of the first embodiment are used to represent the same or similar components.

Referring to FIG. 1B, an encapsulation structure 100 of the disclosure may also be disposed on a back light surface 100b of the solar cell module. The encapsulation structure 100 is consisted of a thermoplastic protective layer 102, a water-barrier layer 108, and an adhesive layer 106. The thermoplastic protective layer 102 is disposed on the outermost layer of the back light surface 100b. In other words, there are no other structural layers present besides the thermoplastic protective layer 102, and the thermoplastic protective layer 102 is directly exposed to the external environment. The material of the thermoplastic protective layer 102 includes a thermoplastic polyurethane (TPU), a thermoplastic polyolefin (TPO), or a thermoplastic elastomer (TPE). The water-barrier layer 108 is disposed between the adhesive layer 106 and the thermoplastic protective layer 102. In an embodiment, the water-barrier layer 108 may be a metal foil, such as aluminum foil, copper foil, or stainless steel foil, but the disclosure is not limited thereto. In another embodiment, the water-barrier layer 108 is, for instance, a light-permeable material such as ultra-thin glass or a polymer having TFE, wherein ultra-thin glass refers to a glass having a thickness of 400 microns or less, alternatively 150 microns or less. If the water-barrier layer 108 is the polymer having TFE, then the polymer having TFE may be, for instance, PC, PEN, PET, fluoropolymer, PVF, ETFE, or PVDF. The material of the adhesive layer 106 is not particularly limited, and may be a thermoplastic adhesive layer or a thermosetting adhesive layer. In an embodiment, the material of the adhesive layer 106 includes TPU, TPO, TPE, or ethylene vinyl acetate (EVA). If the same material is used for the adhesive layer 106 and the thermoplastic protective layer 102, then the same process conditions may be applied during encapsulation to facilitate process control.

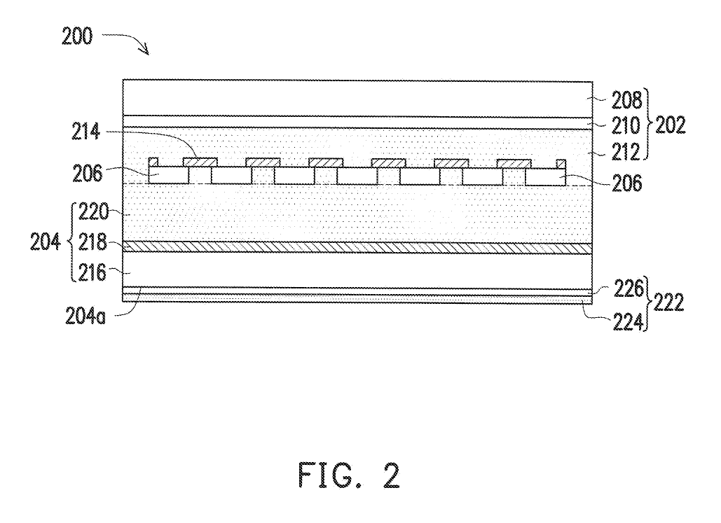

FIG. 2 is a schematic of a solar cell module according to the third embodiment of the disclosure.

Referring to FIG. 2, a solar cell module 200 includes a front plate encapsulation structure 202, a backplate encapsulation structure 204, and a plurality of solar cells 206 encapsulated between the front plate encapsulation structure 202 and the backplate encapsulation structure 204. The solar cells 206 are, for instance, CIGS solar cells, monocrystalline silicon solar cells, polycrystalline silicon solar cells, amorphous silicon solar cells, CdTe solar cells, perovskite solar cells, or a combination of the solar cells, such as tandem solar cells. In an embodiment, the solar cells 206 form a solar cell group connected in parallel and series. The front plate encapsulation structure 202 is consisted of a first thermoplastic protective layer 208, a first water-barrier layer 210, and a first adhesive layer 212, wherein the first water-barrier layer 210 is disposed between the first thermoplastic protective layer 208 and the first adhesive layer 212. The material of the first thermoplastic protective layer 208 in the present embodiment includes TPU, TPO, or TPE, and in terns of preventing yellowing, TPU may adopt aliphatic TPU. In the present embodiment, the first thermoplastic protective layer 208 is disposed on the outermost layer of the solar cell module 200, and therefore when the surface of the first thermoplastic protective layer 208 is damaged by, for instance, scratching, the scratch may be repaired by heating.

Referring further to FIG. 2, the first water-barrier layer 210 is a transparent water-barrier layer such that light may be incident on the internal solar cells 206 from outside of the front plate encapsulation structure 202. The first water-barrier layer 210 may be ultra-thin glass or a polymer having TFE, wherein the ultra-thin glass refers to glass having a thickness of 400 microns or less (alternatively 150 microns or less). If the first water-barrier layer 210 is the polymer having TFE, then the polymer having TFE may include, for instance, PC, PEN, PET, fluoropolymer, PVF, ETFE, or PVDF. The first adhesive layer 212 is not limited to a thermoplastic adhesive layer or a thermosetting adhesive layer. For instance, the material of the first adhesive layer 212 is, for instance, TPU, TPO, TPE, or EVA. If the same material is used for the first adhesive layer 212 and the first thermoplastic protective layer 208, then the same process conditions may be applied during encapsulation to facilitate process control. The solar cells 206 are directly in contact with the first adhesive layer 212 and connected in parallel and series by wires 214 (such as ribbon or copper wires).

In the present embodiment, the backplate encapsulation structure 204 may be consisted of a second thermoplastic protective layer 216, a second water-barrier layer 218, and a second adhesive layer 220, wherein the second water-barrier layer 218 is disposed between the second thermoplastic protective layer 216 and the second adhesive layer 220. The material of the second thermoplastic protective layer 216 may be, but not limited to, for instance, TPU, TPO, or TPE. The second water-barrier layer 218 is, for instance, a metal foil, a glass having a thickness of 400 microns or less (alternatively 150 microns or less) (i.e. ultra-thin glass), or a polymer having TFE. If the second water-barrier layer 218 is the polymer having TFE, then the polymer having TFE may be, for instance, PC, PEN, PET, fluoropolymer, PVF, ETFE, or PVDF. If the second water-barrier layer 218 is a metal foil, then the second water-barrier layer 218 may adopt, for instance, aluminum foil, copper foil, or stainless steel foil, but the disclosure is not limited thereto. When the first water-barrier layer 210 and the second water-barrier layer 218 in the front plate encapsulation structure 202 and the backplate encapsulation structure 204 are both flexible, the solar cell module 200 which is made from aforementioned materials may also be flexible. The second adhesive layer 220 may include but not limited to a thermoplastic adhesive layer or a thermosetting adhesive layer. In an embodiment, the material of the second adhesive layer 220 is, for instance, TPU, TPO, TPE, or EVA. In terms of bonding compatibility, the second adhesive layer 220 and the first adhesive layer 212 may adopt the same material. Therefore, the solar cells 206 are directly in contact with the second adhesive layer 220 and the first adhesive layer 212 after encapsulation, and the interface (dotted line) between the first adhesive layer 212 and the second adhesive layer 220 is not readily distinguished due to fusion. In an embodiment, the backplate encapsulation structure 204 may also be directly bonded to a glass front plate and an adhesive layer to form a solar cell module.

Moreover, the solar cell module 200 of the present embodiment may also include a pattern layer 222 disposed on an outer surface 204a of the backplate encapsulation structure 204 that is aesthetic or suitable for commercial (advertising) use while generating electricity by absorbing sunlight. The pattern layer 222 includes, for instance, an ink layer 224 and a white pigment layer 226 disposed between the ink layer 224 and the second thermoplastic protective layer 216, wherein the white pigment layer 226 is, for instance, a white material such as titanium oxide used as a white underlayer to allow the color and pattern of the ink layer 224 to stand out. In terms of the formability of the pattern layer 222, the material of the second thermoplastic protective layer 216 may adopt TPU.

To verify the effects above, experiments are provided below, but the disclosure is not limited to the experiments below.

### EXPERIMENTAL EXAMPLE 1

TPU/transparent water-barrier layer/TPU structure was used as the encapsulation structure of the front plate, TPU/aluminum foil (about 20 microns)/TPU structure was used as the encapsulation structure of the backplate, and the materials of the encapsulation structures of the front plate and the backplate were cut into a size greater than that of the solar cell module (about slightly greater than 1 cm at the edge). After stacking above structures, the lamination was performed on the stack of the encapsulation materials at 120° C./15 min. The encapsulation for front plate and backplate of a module was complete after the encapsulation materials were cooled.

Next, a water permeability test was performed at a humidity of 85% in a 40° C. environment, wherein the transparent water-barrier layer was UBSF-510 made by 3M. The results are shown in Table 1 below.

### COMPARATIVE EXAMPLE 2

The materials of the encapsulation structures of the front plate and the backplate were changed to ETFE/EVA, and the other conditions were the same as those of experimental example 1, and a water permeability test was performed at a humidity of 85% in a 40° C. environment after lamination. The results are shown in Table 1 below.

TABLE 1

| | | | Front plate of |
|---|---|---|---|
| | | Backplate of | experimental |
| | | experimental | example 1 |
| | Comparative | example 1 | (TPU/transparent |
| Encapsulation | example 1 | (TPU/aluminum | water-barrier |
| material | (ETFE/EVA) | foil/TPU) | layer/TPU) |
| Water | >10 | 1.57E−4 | 4.62E−2 |
| permeability | | | |
| (g/m²-24 hr) | | | |

It may be known from Table 1 that, the water permeability of ETFE/EVA is greater than 10, the water permeability of TPU/transparent water-barrier layer/TPU is 4.62E-2 g/m²-24 hrs, and the water permeability of TPU/aluminum foil/TPU is 1.57E-4 g/m²-24 hrs, indicating that the disclosure has good water-barrier capability and also simplify the encapsuation structure of the solar cell.

### EXPERIMENTAL EXAMPLE 2

A titanium oxide underlayer was first printed on the surface of a TPU film, and then a pattern was printed on the titanium oxide underlayer using an inkjet printer to complete the manufacture of the pattern layer. Next, a cross-cut test (anti-tear test) was performed on the pattern layer on the TPU film, and the results indicate the pattern layer was barely torn off

### COMPARATIVE EXAMPLE 2

The pattern layer was made using the same method as experimental example 2, but the TPU film as changed to an ETFE film. Next, a cross-cut test (anti-tear test) was performed on the pattern layer on the ETFE film, and the results indicate most of the pattern layer was torn off

Based on the above, in the disclosure, via a specific encapsulation structure, the solar cell encapsulation structure may be simplified to distinguish from current solar cell encapsulation structures to achieve the effects of high light transmittance and low water permeability and the features of lightweight and flexibility. At the same time, the life and reliability of the solar cell module may also be increased. Therefore, the module of the disclosure may be applied in portable and wearable mobile power-generating devices.

It will be apparent to those skilled in the art that various modifications and variations may be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. An encapsulation structure of a solar cell module disposed on a light incident surface of the solar cell module, wherein the encapsulation structure is consisted of the following layers:
a thermoplastic protective layer disposed on an outermost layer of the light incident surface, wherein a material of the thermoplastic protective layer comprises thermoplastic polyurethane (TPU), thermoplastic polyolefin (TPO), or thermoplastic elastomer (TPE);
an adhesive layer; and
a transparent water-barrier layer disposed between the adhesive layer and the thermoplastic protective layer.

2. The encapsulation structure of the solar cell module of claim 1, wherein the transparent water-barrier layer comprises a glass having a thickness of 400 microns or less or a polymer having a thin-film encapsulation (TFE).

3. The encapsulation structure of the solar cell module of claim 2, wherein the polymer having the TFE comprises polycarbonate (PC), polyethylene naphthalate (PEN), polyethylene terephthalate (PET), a fluoropolymer, polyvinyl fluoride (PVF), ethylene tetrafluoroethylene (ETFE), or polyvinylidene difluoride (PVDF).

4. The encapsulation structure of the solar cell module of claim 1, wherein the adhesive layer is a thermoplastic adhesive layer or a thermosetting adhesive layer.

5. The encapsulation structure of the solar cell module of claim 1, wherein a material of the adhesive layer comprises TPU, TPO, TPE, or ethylene vinyl acetate (EVA).

6. An encapsulation structure of a solar cell module disposed on a back light surface of the solar cell module, wherein the encapsulation structure is consisted of the following layers:
a thermoplastic protective layer disposed on an outermost layer of the back light surface, wherein a material of the thermoplastic protective layer comprises thermoplastic polyurethane (TPU), thermoplastic polyolefin (TPO), or thermoplastic elastomer (TPE);
an adhesive layer; and
a water-barrier layer disposed between the adhesive layer and the thermoplastic protective layer.

7. The encapsulation structure of the solar cell module of claim 6, wherein the water-barrier layer comprises a metal foil, a glass having a thickness of 400 microns or less, or a polymer having a thin-film encapsulation (TFE).

8. The encapsulation structure of the solar cell module of claim 7, wherein the polymer having the TFE comprises polycarbonate (PC), polyethylene naphthalate (PEN), polyethylene terephthalate (PET), a fluoropolymer, polyvinyl fluoride (PVF), ethylene tetrafluoroethylene (ETFE), or polyvinylidene difluoride (PVDF).

9. The encapsulation structure of the solar cell module of claim 6, wherein the adhesive layer is a thermoplastic adhesive layer or a thermosetting adhesive layer.

10. The encapsulation structure of the solar cell module of claim 6, wherein a material of the adhesive layer comprises TPU, TPO, TPE, or ethylene vinyl acetate (EVA).

11. A solar cell module, comprising:
a front plate encapsulation structure;
a backplate encapsulation structure; and
a plurality of solar cells encapsulated between the front plate encapsulation structure and the backplate encapsulation structure, wherein
the front plate encapsulation structure is consisted of a first thermoplastic protective layer, a first water-barrier layer, and a first adhesive layer, wherein the first water-barrier layer is disposed between the first thermoplastic protective layer and the first adhesive layer,
a material of the first thermoplastic protective layer comprises thermoplastic polyurethane (TPU), thermoplastic polyolefin (TPO), or thermoplastic elastomer (TPE),
the first water-barrier layer is a transparent water-barrier layer, and
the solar cells are directly in contact with the first adhesive layer.

12. The solar cell module of claim 11, wherein the first thermoplastic protective layer is disposed on an outermost layer of the solar cell module.

13. The solar cell module of claim 11, wherein the first water-barrier layer comprises a glass having a thickness of 400 microns or less or a polymer having a thin-film encapsulation (TFE).

14. The solar cell module of claim 13, wherein the first water-barrier layer is a polymer having the TFE, comprising polycarbonate (PC), polyethylene naphthalate (PEN), polyethylene terephthalate (PET), a fluoropolymer, polyvinyl fluoride (PVF), ethylene tetrafluoroethylene (ETFE), or polyvinylidene difluoride (PVDF).

15. The solar cell module of claim 11, wherein the first adhesive layer is a thermoplastic adhesive layer or a thermosetting adhesive layer.

16. The solar cell module of claim 11, wherein a material of the first adhesive layer comprises TPU, TPO, TPE, or ethylene vinyl acetate (EVA).

17. The solar cell module of claim 11, wherein the backplate structure is consisted of a second thermoplastic protective layer, a second water-barrier layer, and a second adhesive layer, and the second water-barrier layer is disposed between the second thermoplastic protective layer and the second adhesive layer.

18. The solar cell module of claim 17, wherein a material of the second thermoplastic protective layer comprises TPU, TPO, or TPE.

19. The solar cell module of claim 17, wherein the solar cells are directly in contact with the second adhesive layer.

20. The solar cell module of claim 17, wherein the second water-barrier layer comprises a metal foil, a glass having a thickness of 400 microns or less or a polymer having a TFE.

21. The solar cell module of claim 20, wherein the second water-barrier layer is the polymer having the TFE, comprising PC, PEN, PET, a fluoropolymer, PVF, ETFE, or PVDF.

22. The solar cell module of claim 17, wherein the second adhesive layer is a thermoplastic adhesive layer or a thermosetting adhesive layer.

23. The solar cell module of claim 17, wherein a material of the second adhesive layer comprises TPU, TPO, TPE, or EVA.

24. The solar cell module of claim 17, further comprising a pattern layer disposed on an outer surface of the backplate encapsulation structure.

25. The solar cell module of claim 24, wherein the pattern layer comprises an ink layer and a white pigment layer disposed between the ink layer and the second thermoplastic protective layer.

26. The solar cell module of claim 11, wherein the solar cells comprise CIGS solar cells, monocrystalline silicon solar cells, polycrystalline silicon solar cells, amorphous silicon solar cells, CdTe solar cells, perovskite solar cells, or a combination of the solar cells.

27. The solar cell module of claim 11, wherein the solar cells form a solar cell group connected in parallel and series.
